(19) United States
(12) Patent Application Publication
(10) Pub. No.: US 2013/0075717 A1
(43) Pub. Date: Mar. 28, 2013

(54) THIN FILM TRANSISTOR

(71) Applicant: JIAN-SHIHN TSANG, Tu-Cheng (TW)

(72) Inventor: JIAN-SHIHN TSANG, Tu-Cheng (TW)

(73) Assignee: HON HAI PRECISION INDUSTRY CO., LTD., Tu-Cheng (TW)

(21) Appl. No.: 13/308,549

(22) Filed: Dec. 1, 2011

(30) Foreign Application Priority Data
Sep. 23, 2011 (TW) 100134268

(51) Int. Cl. H01L 29/12

(52) U.S. Cl. 257/43; 257/E29.068

(57) ABSTRACT

A thin film transistor for a semiconductor device is disclosed. The thin film transistor comprises a substrate; a channel region formed on the substrate, the channel region being made of a first oxide semiconductor material; a source region and a drain region formed on each of lateral sides of the channel region, the source region and the drain region being made of a second oxide semiconductor material, the second oxide semiconductor material having a band gap smaller than a band gap of the first oxide semiconductor material; a gate electrode formed on the channel region; and a gate insulating layer sandwiched between the gate electrode and the channel region.

### BACKGROUND

1. Technical Field

The disclosure generally relates to semiconductor devices, and particularly to thin film transistors.

2. Description of Related Art

A typical thin film transistor includes a channel region, a source region and a drain region formed at two opposite ends of the channel region. Generally, the source region and the drain region are formed by highly doping impurities from an upper surface of the channel region. However, the doping process may be complicated and may need to be proceeded in an ion implanting apparatus, which may increase cost of the thin film transistor.

What is needed, therefore, is an improved thin film transistor to overcome the above described shortcomings.

### BRIEF DESCRIPTION OF THE DRAWINGS

FIG. 1 is an isometric cross section of a thin film transistor in accordance with a first embodiment of the present disclosure.

FIG. 2 is an isometric cross section of a thin film transistor in accordance with a second embodiment of the present disclosure.

FIG. 3 is an isometric cross section of a thin film transistor in accordance with a third embodiment of the present disclosure.

### DETAILED DESCRIPTION

Embodiments of thin film transistors will now be described in detail below and with reference to the drawings.

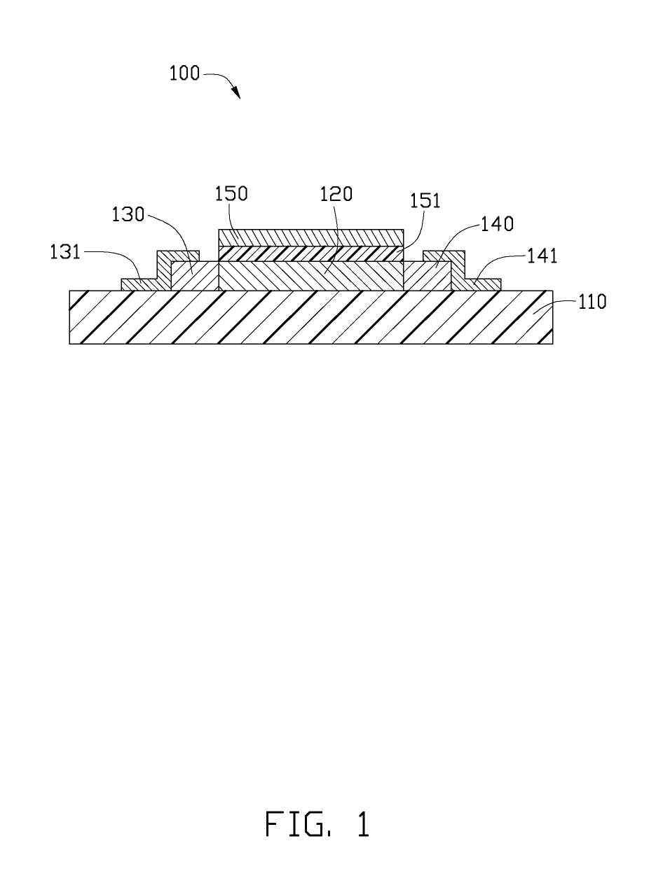

Referring to FIG. 1, a thin film transistor 100 in accordance with a first embodiment comprises a substrate 110, a channel region 120, a source region 130, a drain region 140, and a gate electrode 150.

The substrate 110 is made of a material selected from a group consisting of glass, quartz, silicone, polycarbonate (PC), polymethyl methacrylate (PMMA), and metal foil.

The channel region 120 is formed on an upper surface of the substrate 110. The source region 130 and the drain region 140 are formed at two lateral portions of the channel region 120, and electrically connected to the channel region 120 respectively. In this embodiment, the channel region 120 is made of a first oxide semiconductor material. The first oxide semiconductor material is selected from a group consisting of indium gallium zinc oxide (IGZO), indium zinc oxide (IZO), aluminum zinc oxide (AZO), gallium zinc oxide (GZO), indium tin oxide (ITO), gallium tin oxide (GTO), aluminum tin oxide (ATO), titanium oxide (TiOx), and zinc oxide (ZnO). The source region 130 and the drain region 140 are made of a second oxide semiconductor material. A band gap of the second oxide semiconductor material is smaller than a band gap of the first oxide semiconductor material. The second oxide semiconductor material is selected from a group consisting of IGZO, IZO, AZO, GZO, ITO, GTO, ATO, TiOx, and ZnO.

The thin film transistor 100 further comprises a source electrode 131 formed on the source region 130, and a drain electrode 141 formed on the drain region 140. The source electrode 131 covers part of an upper surface of the source region 130 remote from the channel region 120, and the source electrode extends to the upper surface of the substrate 110. Similarly, the drain electrode 141 covers part of an upper surface of the drain region 140 remote from the channel region 120, and the drain electrode extends to the upper surface of the substrate 110. The source electrode 131 and the drain electrode 141 are spaced from the channel region 120. The source electrode 131 and the drain electrode 141 are configured to be electrically connected to external electrical sources, thereby providing driving voltages to the thin film transistor 100.

The gate electrode 150 is positioned above the channel region 120, and a gate insulating layer 151 is sandwiched between the gate electrode 150 and the channel region 120. When the thin film transistor 100 is in use, voltages applied to the gate electrode 150 will control working states of the thin film transistor 100. For example, for an enhanced thin film transistor 100, when the gate electrode 150 is applied with a voltage greater than a threshold voltage of the thin film transistor 100, an electrical conductive channel will be formed in the channel region 120 to connect the source region 130 with the drain region 140, and the thin film transistor 100 is in an “on” state. When the gate electrode 150 is applied with a voltage of OV, the electrical conductive channel will disappear in the channel region 120, and the thin film transistor 100 is in an “off” state. In this embodiment, the gate electrode 150 is made of a material selected from a group consisting of Au, Ag, Al, Cu, Cr, and alloys thereof. The gate insulating layer 151 is made of a material selected from a group consisting of SiOx, SiNx, SioNx, Ta₂O₅, and HfO₂.

In the thin film transistor 100 described above, the second oxide semiconductor material of the source region 130 and the drain region 140 has a band gap smaller than that of the first oxide semiconductor material of the channel region 120. Therefore, the source region 130 and the drain region 140 will have a relatively higher concentration of carriers and better conductive property than the channel region 120. Taking indium gallium zinc oxide (IGZO) for example, the source region 130 and the drain region 140 are made of In₂Ga₂ZnO₇ material, and the channel region 120 is made of InGaZnO₄ material. And, a band gap of the In₂Ga₂ZnO₇ material is smaller than that of the InGaZnO₄ material. For a conventional semiconductor material, a concentration of carrier can be determined by the following formula:

N_{c}*Nₚ=nᵢ²=BT³exp(−Eg/kT)

Wherein N_{c} represents a concentration of n-type carriers; Nₚ represents a concentration of p-type carriers; nᵢ represents a concentration of intrinsic carriers; B represent a constant corresponding to the material; T represents the absolute temperature; Eg represents a band gap; and k represents Boltzmann constant.

According to the formula described above, under a same temperature, the smaller the band gap is, the larger the concentration of intrinsic carriers nᵢ will be. Therefore, a multiplication of the concentration of n-type carriers N_{c} and the concentration of p-type carriers Nₚ will increase. Generally, in a material of IGZO, IZO or ITO, when a ratio of In atoms to a total number of metal atoms increases, a band gap of the material decreases. For example, in In₂Ga₂ZnO₇ material, a ratio of In atoms to a total number of metal atoms is 40%. And in InGaZnO₄ material, a ratio of In atoms to a total number of metal atoms is 33.3%. Therefore, a band gap of the In₂Ga₂ZnO₇ material is smaller than that of the InGaZnO₄ material. In addition, in a material of AZO or ATO, when a ratio of Al atoms to a total number of metal atoms increases, a band gap of the material increases.

In the thin film transistor 100 described above, the source region 130 and the drain region 140 are made of the second oxide semiconductor material with a band gap smaller than that of the first oxide semiconductor material. Under a same temperature, the source region 130 and the drain region 140 will have a higher concentration of carriers than the channel region 120. As a result, the steps of doping impurities into the source region 130 and the drain region 140 may be omitted. A simplified manufacture process of the thin film transistor 100 may be used and the cost of the thin film transistor 100 may be reduced.

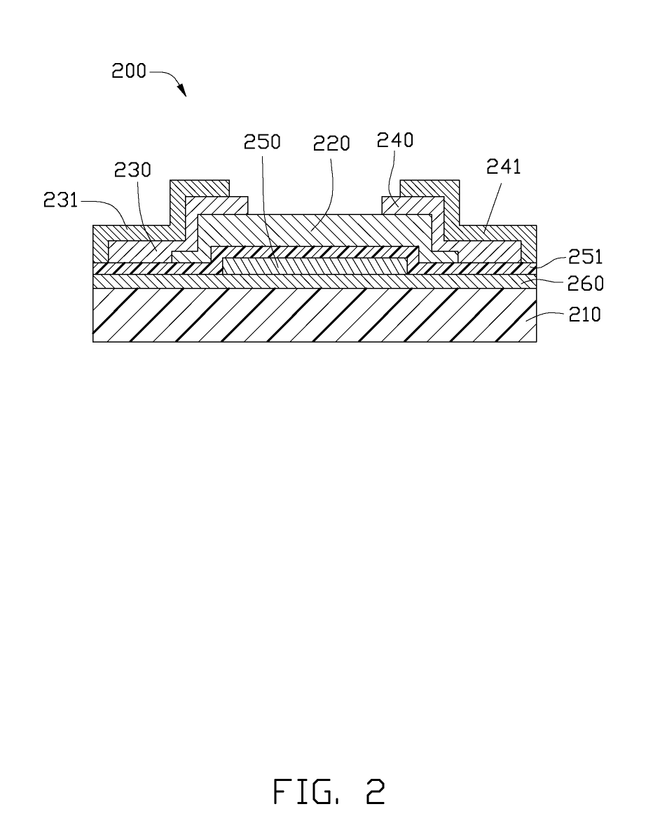

The gate electrode is not limited to be formed above the channel region. Referring to FIG. 2, a thin film transistor 200 in accordance with a second embodiment comprises a substrate 210, a channel region 220, a source region 230, a drain region 240, a gate electrode 250, and an adhesive layer 260. The source region 230 and the drain region 240 are formed at two lateral portions of the channel region 220, and electrically connected to the channel region 220. The gate electrode 250 is formed below the channel region 220. The thin film transistor 200 further comprises a gate insulating layer 251 sandwiched between the gate electrode 250 and the channel layer 220, and extending to bottom surfaces of the source region 230 and the drain region 240. The adhesive layer 260 is formed on an upper surface of the substrate 210, and connects the substrate 210 with the gate electrode 250 and gate insulating layer 251. The adhesive layer 260 is made of insulating materials or conductive materials. Each of the source region 230 and the drain region 240 extends to overlap an upper surface of the channel region 220. The thin film transistor 200 further comprises a source electrode 231 formed on the source region 230, and a drain electrode 241 formed on the drain region 240. The source electrode 231 is formed on part of an upper surface of the source region 230, and the source electrode extends to an upper surface of the gate insulating layer 251. The drain electrode 241 is formed on part of an upper surface of the drain region 240, and the drain electrode extends to the upper surface of the gate insulating layer 251.

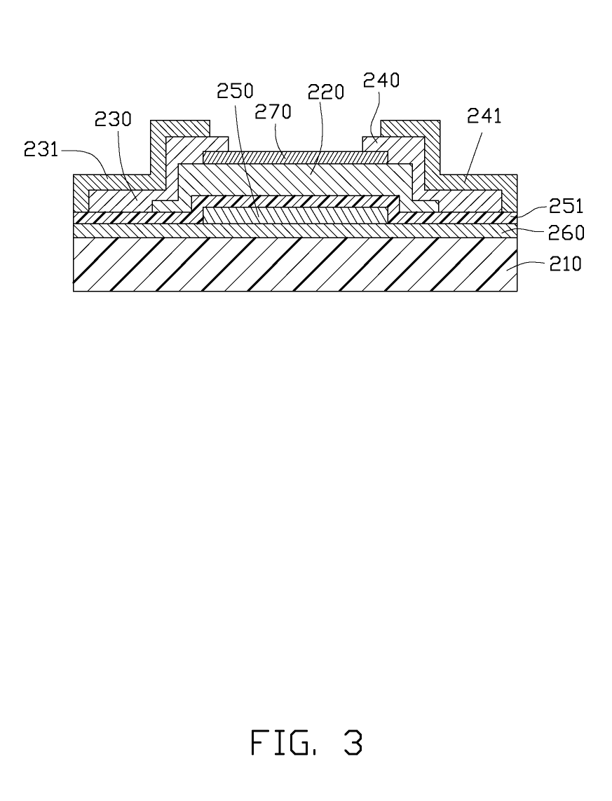

Referring to FIG. 3, the thin film transistor 200 may further comprises an etch stop layer 270. The etch stop layer 270 is formed on the upper surface of the channel region 220 facing away from the gate insulating layer 251. Two lateral sides of the etch stop layer 270 are respectively covered by the source region 230 and the drain region 240. In this embodiment, the etch stop layer 270 is made of SiO₂. The etch stop layer 270 is configured to prevent dust and gas or hydrosphere from penetrating into the channel layer 220.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A thin film transistor, comprising:
a substrate;
a channel region formed on the substrate, the channel region being made of a first oxide semiconductor material;
a source region and a drain region formed on each of lateral sides of the channel region, the source region and the drain region being made of a second oxide semiconductor material, the second oxide semiconductor material having a band gap smaller than a band gap of the first oxide semiconductor material;
a gate electrode formed on the channel region; and
a gate insulating layer sandwiched between the gate electrode and the channel region.

2. The thin film transistor of claim 1, wherein the first oxide semiconductor material is selected from a group consisting of IGZO, IZO, AZO, GZO, ITO, GTO, ATO, TiOx, and ZnO.

3. The thin film transistor of claim 1, wherein the second oxide semiconductor material is selected from a group consisting of IGZO, IZO, AZO, GZO, ITO, GTO, ATO, TiOx, and ZnO.

4. The thin film transistor of claim 1, wherein the first oxide semiconductor material and the second oxide semiconductor material are selected from IGZO, IZO, or ITO; and the second oxide semiconductor material has a ratio of a number of indium (In) atoms to a total number of metal atoms higher than a ratio of a number of In atoms to a total number of metal atoms of the first oxide semiconductor material.

5. The thin film transistor of claim 1, wherein the first oxide semiconductor material and the second oxide semiconductor material are selected from AZO, or ATO; and the second oxide semiconductor material has a ratio of a number of aluminum (Al) atoms to a total number of metal atoms higher than a ratio of a number of Al atoms to a total number of metal atoms of the first oxide semiconductor material.

6. The thin film transistor of claim 1, wherein a source electrode is formed on an upper surface of the source region; and a drain electrode is formed on an upper surface of the drain region.

7. A thin film transistor, comprising:
a substrate;
a channel region formed on the substrate, the channel region being made of a first oxide semiconductor material;
a source region and a drain region formed on the substrate; wherein the source regions and the drain region are electrically connected to the channel region; the source region and the drain region are made of a second oxide semiconductor material; and the second oxide semiconductor material has a band gap smaller than a band gap of the first oxide semiconductor material; and
a gate electrode electrically connected to the channel region, and is spaced from the source region and the drain region.

8. The thin film transistor of claim 7, wherein the first oxide semiconductor material is selected from a group consisting of IGZO, IZO, AZO, GZO, ITO, GTO, ATO, TiOx, and ZnO.

9. The thin film transistor of claim 7, wherein the second oxide semiconductor material is selected from a group consisting of IGZO, IZO, AZO, GZO, ITO, GTO, ATO, TiOx, and ZnO.

10. The thin film transistor of claim 7, wherein the first oxide semiconductor material and the second oxide semiconductor material are selected from IGZO, IZO, or ITO; and the second oxide semiconductor material has a ratio of a number of indium (In) atoms to a total number of metal atoms higher than a ration of a number of In atoms to a total number of metal atoms of the first oxide semiconductor material.

11. The thin film transistor of claim 7, wherein the first oxide semiconductor material and the second oxide semiconductor material are selected from AZO, or ATO; and the second oxide semiconductor material has a ratio of a number aluminum (Al) atoms to a total number of metal atoms higher than a ratio of a number of Al atoms to a total number of metal atoms of the first oxide semiconductor material.

12. The thin film transistor of claim 7, wherein a source electrode is formed on an upper surface of the source region; and a drain electrode is formed on an upper surface of the drain region.

13. The thin film transistor of claim 7, wherein the gate electrode is formed between the substrate and the channel region.

14. The thin film transistor of claim 13, further comprising an adhesive layer formed between and interconnecting the substrate and the gate electrode; and a gate insulating layer formed between the gate electrode and the channel region, the gate insulating layer electrically insulate the gate electrode from the source region and the drain region.

15. The thin film transistor of claim 14, further comprising an etch stop layer formed on an upper surface of the channel region, facing away from the gate insulating layer; the source region and the drain region overlapping on parts of an upper surface of the etch stop layer.

16. The thin film transistor of claim 7, further comprising a gate insulating layer formed between and interconnecting the channel region and the gate electrode; wherein the channel region directly contacts the substrate, and the gate electrode is formed on the channel region with the gate insulating layer between the channel region and the gate electrode.

17. A thin film transistor, comprising:
a substrate;
a channel region formed on the substrate, the channel region being made of a first oxide semiconductor material; and
a source region and a drain region formed on each of lateral sides of the channel region, the source region and the drain region being made of a second oxide semiconductor material, the second oxide semiconductor material having a concentration of carriers greater than a concentration of carriers of the first oxide semiconductor material.

18. The thin film transistor of claim 17, wherein the first oxide semiconductor material and the second oxide semiconductor material are selected from IGZO, IZO, or ITO; and the second semiconductor material has a ratio of a number of indium (In) atoms to a total number of metal atoms higher than a ratio of a number of In atoms to a total number of metal atoms of the first oxide semiconductor material.

19. The thin film transistor of claim 17, wherein the first oxide semiconductor material and the second oxide semiconductor material are selected from AZO, or ATO; and the second semiconductor material has a ratio of a number of aluminum (Al) atoms to a total number of metal atoms higher than a ratio of a number of Al atoms to a total number of metal atoms of the first oxide semiconductor material.
